(19) United States
(12) Patent Application Publication
(10) Pub. No.: US 2025/0251290 A1
(43) Pub. Date: Aug. 7, 2025

(54) RESISTOR VOLTAGE-BEARING TYPE ON-STATE VOLTAGE DROP MEASUREMENT CIRCUIT FOR JUNCTION TEMPERATURE MONITORING AND MONITORING METHOD

(71) Applicant: Southwest Jiaotong University, Chengdu (CN)

(72) Inventors: Wensheng Song, Chengdu (CN); Haoyang Tan, Chengdu (CN); Kexin Yang, Chengdu (CN); Jian Chen, Chengdu (CN); Tao Tang, Chengdu (CN); Pengcheng Xu, Chengdu (CN); Chenwei Ma, Chengdu (CN); Xinglai Ge, Chengdu (CN)

(21) Appl. No.: 19/047,758

(22) Filed: Feb. 7, 2025

Related U.S. Application Data
(63) Continuation of application No. PCT/CN2024/135530, filed on Nov. 29, 2024.

(30) Foreign Application Priority Data
Feb. 4, 2024 (CN) 202410156868.4

(51) Int. Cl. G01K 7/01

(52) U.S. Cl. CPC G01K 7/015; G01K 2217/00

(57) ABSTRACT

The present invention discloses a resistor voltage-bearing type on-state voltage drop measurement circuit for junction temperature monitoring and a monitoring method. The measurement circuit includes a high-resistance series high-voltage resistor R_{L}, switching diodes D₁ and D₂, a low-voltage MOSFET M₁, an inverter U₁, a three-state gate U₂, an RC delay circuit consisting of a resistor R₁ and a capacitor C₁, current-limiting resistors R₂ and R₃, auxiliary voltage sources VDD and VCC, an operational amplifier U₃, and an isolation operational amplifier U₄. and the monitoring method includes: designing an on-state voltage drop sampling circuit based on the high-resistance resistor and selecting parameters according to an actual application scenario; measuring a collector current and an on-state voltage drop model at different junction temperatures under an offline condition, and providing a calculation model for online monitoring; and performing online monitoring on the junction temperature.

### CROSS-REFERENCE TO RELATED APPLICATIONS

This application is a continuation of International Application No. PCT/CN2024/135530, filed on Nov. 29, 2024, which claims priority to Chinese Patent Application No. 202410156868.4, filed with the China National Intellectual Property Administration on Feb. 4, 2024. Both of which are hereby incorporated by reference in their entireties.

### TECHNICAL FIELD

The present invention belongs to the field of online monitoring of power device junction temperature, and particularly relates to a resistor voltage-bearing type on-state voltage drop measurement circuit for junction temperature monitoring and a monitoring method.

### BACKGROUND

An insulated gate bipolar transistor (IGBT) is a power semiconductor device most widely used in a power system, and is widely applied to high-power conversion scenarios such as rail transit. The reliability of the IGBT is always a main factor for restricting improvement of the reliability of a converter. Statistically, more than 33% of converter failures come from IGBT. The lifetime and reliability of power semiconductor devices are mainly affected by the average junction temperature and temperature fluctuations. Therefore, it is an effective method to improve the lifetime of IGBT by monitoring and controlling the junction temperature.

The existing IGBT junction temperature monitoring methods mainly include four types: a built-in thermistor method, an optical thermometry method, a thermal impedance network model method, and a thermo-sensitive electrical parameter method. Among these methods, the thermistor method has a low response speed, the thermistor is far away from a chip, and a difference between a measurement result and actual IGBT junction temperature is large; consequently, the obtained temperature has no great reference significance. The optical thermometry is expensive and generally used in a laboratory environment because the optical thermometry requires destructive processing of the chip. The thermal impedance network method cannot directly obtain junction temperature information, and cannot meet a requirement for online measurement of IGBT junction temperature due to the influence of aging. Among these methods, the thermo-sensitive electrical parameters have attracted much attention due to high precision, fast response speed, and strong online monitoring capabilities.

In the existing thermo-sensitive electrical parameter, the on-state voltage drop is the most concerned due to excellent comprehensive performance in sensitivity and response speed. In addition, the on-state voltage drop is the only online monitoring method for IGBT junction temperature that has been applied in practical engineering. The current on-state voltage drop measurement is classified into measurement under low current and measurement under high current. The on-state voltage drop measurement under low current has become a standard measurement method and is widely applied to various offline measurements of IGBT due to extremely high accuracy and the fact that the measurement current does not interfere with the IGBT junction temperature. However, during the actual online operation of the converter, the IGBT is in a large-current and high-voltage working condition. To achieve the online monitoring of the IGBT junction temperature by using the on-state voltage drop, the on-state voltage drop online monitoring circuit is required to have good high-voltage isolation capability and extremely high measurement accuracy.

At present, the online measurement circuit for on-state voltage drop is mainly used for measuring the on-state voltage drop of low-voltage IGBT. The high-voltage isolation design and circuit reliability of the online measurement circuit for on-state voltage drop are important factors that restrict the application of the measurement circuit in high-voltage occasions.

### SUMMARY

To solve the above problems, the present invention provides a resistor voltage-bearing type on-state voltage drop measurement circuit for junction temperature monitoring and a monitoring method.

A resistor voltage-bearing type on-state voltage drop measurement circuit for junction temperature monitoring according to the present invention includes a high-resistance series high-voltage resistor R_{L}, a switching diode D₁, a switching diode D₂, a low-voltage metal-oxide-semiconductor field-effect transistor (MOSFET) M₁, an inverter U₁, a three-state gate U₂, an RC delay circuit consisting of a resistor R₁ and a capacitor C₁, a current-limiting resistor R₂, a current-limiting resistor R₃, auxiliary voltage sources VDD and VCC, an operational amplifier U₃, and an isolation operational amplifier U₄. One end of the high-resistance series high-voltage resistor R_{L} is connected to a collector of IGBT, the other end of the high-resistance series high-voltage resistor R_{L} is connected to a positive electrode of the switching diode D₁, a negative electrode of the switching diode D₁ is connected to a drain of the low-voltage MOSFET M₁, and a source of the low-voltage MOSFET M₁ is connected to an emitter of the IGBT; a connection between a positive electrode of the switching diode D₁ and the high-resistance series high-voltage resistor R_{L} is a test point and is connected to an input end of the operational amplifier U₃ of an isolation part, a negative electrode of the switching diode D₂ is connected to the test point, and a positive electrode of the switching diode D₂ is connected to power reference ground; and the auxiliary voltage source VDD is connected to the negative electrode of the switching diode D₁ by the current-limiting resistor R₃.

In a circuit of a logic part, an input signal of the circuit is from a control signal of IGBT sent by a controller, the signal is inverted by the inverter U₁, and then input to an input end of the three-state gate U₂ by the series RC delay circuit, and an input signal of a control end of the three-state gate U₂ is the control signal of the IGBT; after passing through three-state gate U₂, the control signal becomes a control signal with a delay added to a falling edge of the signal after inversion, and this control signal is finally used for switching control of the low-voltage MOSFET M₁.

In a circuit of an isolation part, an input signal of the circuit is from a test point voltage ν_{TP} of a measurement part, and the operational amplifier U₃ is connected as a voltage follower, and a voltage of the voltage follower is finally used for on-state voltage drop detection by the isolation operational amplifier U₄.

In addition, the circuit also has an output parasitic capacitance C_{O} from the low-voltage MOSFET M₁, a junction capacitance C_{R} of the switching diode D₁ and the switching diode D₂, an input capacitance of the operational amplifier U₃ and a PCB parasitic capacitance C_{S}, which are connected to the test point voltage ν_{TP}.

When the IGBT is on-state, the low-voltage MOSFET M₁ is turned off according to the control signal, the switching diode D₁ is in a reverse bias state, and the test point voltage ν_{TP} is equivalent IGBT on-state voltage drop ν_{CE-ON}; when the IGBT is turned off, the low-voltage MOSFET M₁ is controlled to be turned on and turned off according to the control signal, the switching diode D₁ is in a forward bias state, high voltage between the collector and the emitter of the IGBT is born by the high-resistance series high-voltage resistor R_{L}, and the test point voltage is clamped to the on-state voltage drop of the switching diode D₁; during the whole process, the high-resistance series high-voltage resistor R_{L} bears high voltage only in the IGBT turn-off process and does not bear high voltage in other periods; and a control signal of the low-voltage MOSFET M₁ is formed by a gate control signal of the IGBT after conditioning of the logic part.

An IGBT junction temperature online monitoring method based on the resistor voltage-bearing type on-state voltage drop measurement circuit includes the following steps:
Step 1: designing an on-state voltage drop sampling circuit based on the high-resistance series high-voltage resistor R_{L} and selecting parameters according to an actual application scenario.

According to a power rating of an actual device, high-resistance series high-voltage resistors R_{L} with different resistances are selected to limit a power dissipation on the resistor to a constant value, a resistance of the high-resistance series high-voltage resistor R_{L} is calculated using the power dissipation combined with an isolation voltage, specifically:

$$R = \frac{{V}_{CE}}{P}$$

wherein P is an allowed power dissipation on the resistor, and V_{CE} is a voltage between the collector and the emitter.

For the switching diode D₁ and the switching diode D₂, any switching diode with a withstand voltage of about 90 V and a rated current level of mA meets requirements.

The operational amplifier U₃ requires a bandwidth of more than 1 MHZ, an input impedance greater than 1000 MΩ, an input capacitance of less than 4 PF, and an input bias current level of nA; and the isolation operational amplifier U₄ only needs to meet a requirement of a system on isolation voltage.

For parameter selection of the RC delay circuit, a delay is added to the low-voltage MOSFET M₁ when the IGBT is turned on, and a delay time of the RC delay circuit is represented as:

$${T}_{D} = R C$$

Specific values of parameters of the capacitor and the resistor may be calculated according to a formula.
Step 2: measuring a collector current i_{C} and an on-state voltage drop model at different junction temperatures under an offline condition, and providing a calculation model for online monitoring.

When IGBT operates in a saturation region, the on-state voltage drop ν_{CE-ON} is represented as:

$${v}_{CE - ON} = \frac{{mkT}_{j}}{q} ln ( \frac{{i}_{C}}{{i}_{S}} + 1 ) + {i}_{C} ( {R}_{N} + {R}_{CH} )$$

wherein m is an injection coefficient, k is a Boltzmann constant, Tⱼ is a junction temperature, q is a charge, i_{C} is the collector current, i_{S} is a reverse saturation current, R_{N} is a module package resistance of the IGBT module, and R_{CH} is an internal on-resistance of the IGBT.

A partial derivative of the collector current i_{C} is calculated for the on-state voltage drop ν_{CE-ON}, wherein a change rate of the on-state voltage drop ν_{CE-ON} to the collector current i_{C} is represented as:

$${k}_{C E} = \frac{\partial {v}_{CE - ON}}{\partial {i}_{C}} = \frac{{nkT}_{j}}{q {i}_{S}} \frac{1}{{i}_{C} + {i}_{S}} + ( {R}_{N} + {R}_{CH} )$$

It can be seen that the change rate of the on-state voltage drop ν_{CE-ON} to the collector current i_{C} changes with i_{C}; when the collector current i_{C} is within a small change range, the change rate is regarded as a constant, and the on-state voltage drop is represented by piecewise linearization based on the collector current i_{C} as follows:

$${v}_{CE - ON} ( {i}_{C} ) = {k}_{n} {i}_{C} + {V}_{INT - n} n = 1 , 2 … n$$

wherein kₙ is the change rate of on-state voltage drop ν_{CE-ON} to the collector current i_{C} within different collector current i_{C} ranges, which is a specific value of k_{CE} in a certain collector current i_{C} region, and n represents different current ranges; V_{INT-n} is a constant term of an expression in each collector current i_{C} range; kₙ and V_{INT-n} are different in different collector current i_{C} ranges; for kₙ, when the collector current i_{C} is within a small change range, kₙ is considered to be a constant independent of the collector current i_{C} but related to the junction temperature Tⱼ according to k_{CE} expression.
kₙ is calculated using a least square method by sampling the on-state voltage drop ν_{CE-ON} and the collector current i_{C} multiple times within a certain current range and is represented as:

$${k}_{n} = \frac{\overline{{v}_{CE - ON} {i}_{C}} - \overline{{v}_{CE - ON} {i}_{C}}}{\overline{{i}_{C}^{2}} - {( \overline{{i}_{C}} )}^{2}}$$

a fitting coefficient Rₙ² is represented as:

$${R}_{n}^{2} = 1 - \frac{\sum {( {v}_{CE - ON} - \overline{{v}_{CE - ON}} )}^{2}}{\sum {( {v}_{CE - ON} - f ( {i}_{C} ) )}^{2}}$$

Step 3: performing online monitoring on the junction temperature under online conditions based on the model obtained from offline condition testing.

In the online monitoring experiment, a power cycle experiment based on a Buck circuit is used to verify the online monitoring effect of the proposed monitoring circuit and monitoring method on the junction temperature, the Buck power cycle test bench dissipates heat from the IGBT by a heat sink, and a temperature of the IGBT is increased or decreased when the IGBT is running continuously by changing a power of the heat sink.

The beneficial technical effects of the present invention are as follows:

The present invention achieves the high-voltage isolation between the collector and the emitter during an IGBT turn-off period and the measurement of the on-state voltage drop during an IGBT turn-on period by utilizing a high-resistance series high-voltage resistor in conjunction with an auxiliary low-voltage device. The proposed circuit has the advantages of low cost, high reliability and adaptability to the measurement of on-state voltage drop in high voltage and a wide ambient temperature range. Compared with the existing circuit, the circuit according to the present invention has better potential for achieving online measurement of junction temperature by utilizing the on-state voltage drop in high-voltage IGBT applications.

### BRIEF DESCRIPTION OF DRAWINGS

FIG. 1 is a structural diagram of a resistor voltage-bearing type on-state voltage drop measurement circuit for junction temperature monitoring according to the present invention.

FIG. 2 is a circuit state diagram of a measurement circuit in IGBT turn-off and turn-on states.

FIG. 3 is an ideal waveform diagram of key nodes of a measurement circuit.

FIG. 4 is a schematic diagram of output characteristics of IGBT at different temperatures and a change rate of on-state voltage drop to a collector current at different currents.

FIG. 5 is a schematic diagram of a comparison between an actual output characteristic curve and a linearized output characteristic curve within a full current range.

FIG. 6 is a schematic diagram of a junction temperature-current segment-on-state voltage drop versus a current change rate model and a junction temperature-on-state voltage drop-current model.

FIG. 7 is a flow chart of a junction temperature online monitoring strategy.

FIG. 8 is a waveform during junction temperature online monitoring.

FIG. 9 is a schematic diagram of a comparison between monitoring results during the junction temperature online monitoring process and measurement results of an infrared camera

### DESCRIPTION OF EMBODIMENTS

The present invention is further described below with reference to the accompanying drawings and specific embodiments.

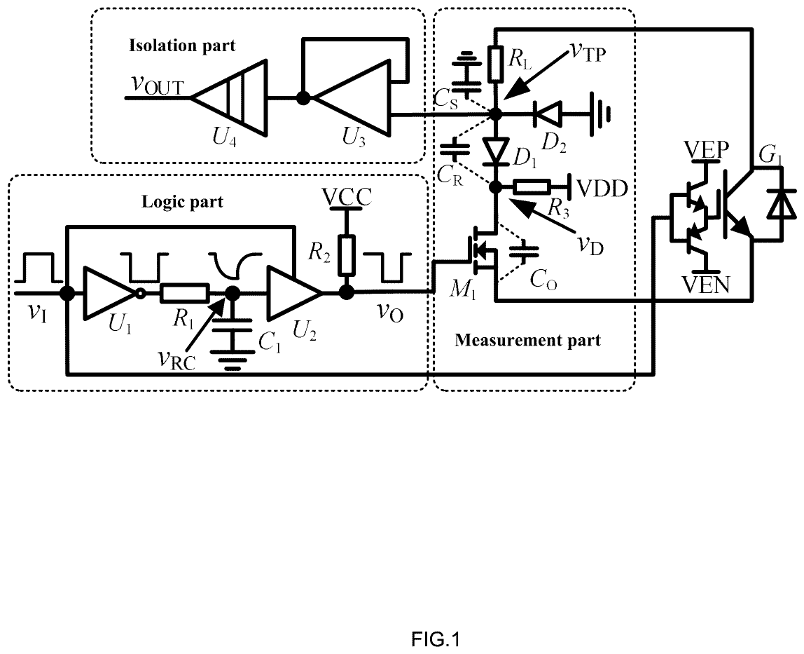

As shown in FIG. 1, a resistor voltage-bearing type on-state voltage drop measurement circuit for junction temperature monitoring according to the present invention includes a high-resistance series high-voltage resistor R_{L}, a switching diode D₁, a switching diode D₂, a low-voltage MOSFET M₁, an inverter U₁, a three-state gate U₂, an RC delay circuit consisting of a resistor R₁ and a capacitor C₁, a current-limiting resistor R₂, a current-limiting resistor R₃, auxiliary voltage sources VDD and VCC, an operational amplifier U₃, and an isolation operational amplifier U₄. One end of the high-resistance series high-voltage resistor R_{L} is connected to a collector of IGBT, the other end of the high-resistance series high-voltage resistor R_{L} is connected to a positive electrode of the switching diode D₁, a negative electrode of the switching diode D₁ is connected to a drain of the low-voltage MOSFET M₁, and a source of the low-voltage MOSFET M₁ is connected to an emitter of the IGBT; a connection between a positive electrode of the switching diode D₁ and the high-resistance series high-voltage resistor R_{L} is a test point and is connected to an input end of the operational amplifier U₃ of an isolation part, a negative electrode of the switching diode D₂ is connected to the test point, and a positive electrode of the switching diode D₂ is connected to power reference ground; and the auxiliary voltage source VDD is connected to the negative electrode of the switching diode D₁ by the current-limiting resistor R₃.

In a circuit of a logic part, an input signal of the circuit is from a control signal of IGBT sent by a controller, the signal is inverted by the inverter U₁, and then input to an input end of the three-state gate U₂ by the series RC delay circuit, and an input signal of a control end of the three-state gate U₂ is the control signal of the IGBT; after passing through three-state gate U₂, the control signal becomes a control signal with a delay added to a falling edge of the signal after inversion, and this control signal is finally used for switching control of the low-voltage MOSFET M₁.

In a circuit of an isolation part, an input signal of the circuit is from a test point voltage ν_{TP} of a measurement part, and the operational amplifier U₃ is connected as a voltage follower, and a voltage of the voltage follower is finally used for on-state voltage drop detection by the isolation operational amplifier U₄.

In addition, the circuit also has an output parasitic capacitance C_{O} from the low-voltage MOSFET M₁, a junction capacitance CR of the switching diode D₁ and the switching diode D₂, an input capacitance of the operational amplifier U₃ and a PCB parasitic capacitance C_{S}, which are connected to the test point.

When the IGBT is on-state, the low-voltage MOSFET M₁ is turned off according to the control signal, the switching diode D₁ is in a reverse bias state, and the test point voltage VTP is equivalent on-state voltage drop ν_{CE-ON}; when the IGBT is turned off, the low-voltage MOSFET M₁ is turned on and turned off according to the control signal, the switching diode D₁ is in a forward bias state, high voltage between the collector and the emitter of the IGBT is born by the high-resistance series high-voltage resistor R_{L}, and the test point voltage is clamped to the on-state voltage drop of the diode; during the whole process, the high-resistance series high-voltage resistor R_{L} bears high voltage only in the IGBT turn-off process and does not bear high voltage in other periods; and a control signal of the low-voltage MOSFET M₁ is formed by a gate control signal of the IGBT after conditioning of the logic part.

The high-resistance series high-voltage resistor R_{L} is the only high-resistance device used in this circuit, and other auxiliary devices are low-voltage devices. Voltage bearing by using a resistor has the advantages of low cost, high reliability, and good parameter consistency. The other auxiliary devices are all low-voltage devices, which have excellent performance, good parameter consistency, and small parameter changes with temperature. Therefore, the entire circuit can operate at a wide range of ambient temperatures, and meanwhile it is easier to ensure the consistency of performance of different measurement circuits during mass production. The resistance of the high-resistance series high-voltage resistor R_{L} ranges from hundreds of kilo-ohms to several mega-ohms, and the high-resistance series high-voltage resistor R_{L} has a very large resistance and cannot cause interference on the normal operation of the IGBT.

An IGBT junction temperature online monitoring method based on the resistor voltage-bearing type on-state voltage drop measurement circuit includes the following steps:
Step 1: designing an on-state voltage drop sampling circuit based on the high-resistance series high-voltage resistor and selecting parameters according to an actual application scenario.

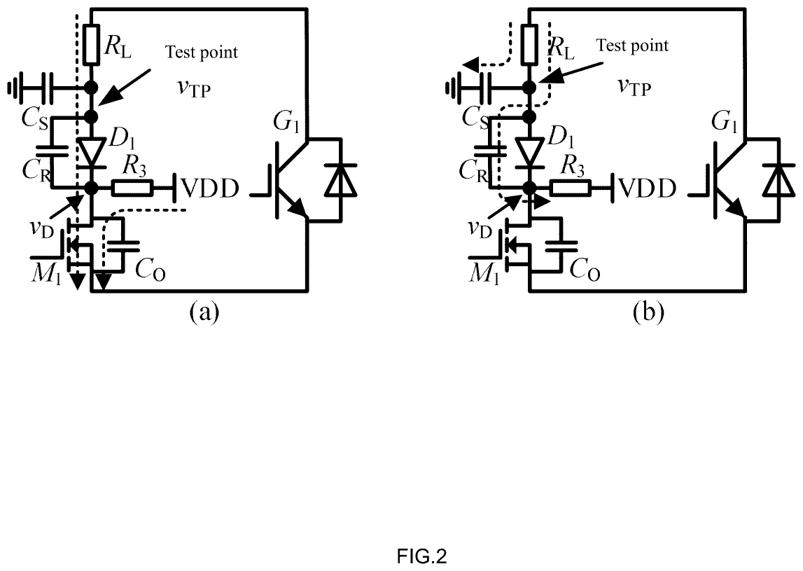

FIG. 2 is a circuit state diagram of a measurement circuit in IGBT turn-off and turn-on states. FIG. 2(a) shows a state of a circuit in a high voltage isolation mode, and FIG. 2(b) shows a state of a circuit in an on-state voltage drop measurement mode.

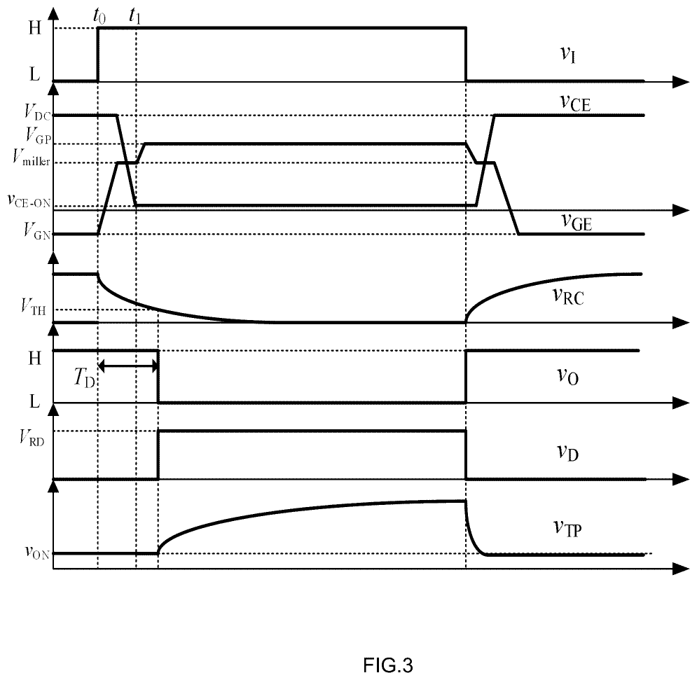

The measurement circuit in the present invention achieves the forward bias and reverse bias control of the diode D₁ by utilizing the turn-on and turn-off control of the low-voltage MOSFET M₁, thereby achieving the measurement of the on-state voltage drop and the isolation of high voltage. FIG. 3 is a waveform diagram of key nodes of a measurement circuit. The signals in FIG. 2 correspond to signals in FIG. 1. H and L represent a high level and a low level in the logic circuit respectively, V_{DC} is a direct current bus voltage, V_{GP} is a high level of an IGBT drive circuit, which is 20 V in this circuit, V_{GN} is a low level of an IGBT drive circuit, which is −8 V in this circuit, and Vₘᵢₗₗₑᵣ is a Miller platform voltage. V_{TH} is a threshold voltage of the low voltage MOSFET M₁, V_{RD} is a voltage of the auxiliary voltage source VDD, and V_{ON} is an on-state voltage drop of the switching diode D₁. To avoid interference to a circuit caused by a certain time required by the voltage of the IGBT to be dropped from the bus voltage to the on-state voltage drop, a delay is added to a control signal of the low-voltage MOSFET M₁ in the turn-on transient of the IGBT to avoid the influence of high voltage on measurement, and the specific delay time is designed according to the actual voltage change time of the used IGBT to ensure that the voltage is completely dropped to the on-state voltage drop in a delay time period. Meanwhile, it should be noted that, since the auxiliary voltage source VDD that forces the switching diode D₁ to reverse bias is only a voltage slightly higher than the on-state voltage drop, even if the low-voltage MOSFET M₁ does not switch, the measurement of the on-state voltage drop is not affected; however, if the low-voltage MOSFET M₁ is not turned on when the IGBT is turned off, the test point is clamped to the voltage of the auxiliary voltage source VDD plus the diode on-state voltage drop, thus affecting the response speed of the circuit.

When the IGBT is turned on, the low voltage MOSFET M₁ is turned off, as shown in FIG. 2(b). According to Kirchhoff's law, the test point voltage VTP and the circuit node voltage ν_{D} may be represented as:

$${V}_{TP} ( s ) = \frac{s {C}_{R} {R}_{L} {v}_{D} ( s ) + {v}_{CE - ON} ( s )}{s {C}_{R} {R}_{L} + s {C}_{S} {R}_{L} + 1}$$

$${v}_{D} ( s ) = \frac{s {C}_{R} {R}_{3} {v}_{TP} ( s ) + {V}_{RD}}{s {C}_{O} {R}_{3} + s {C}_{R} {R}_{3} + 1}$$

wherein C_{R}, R_{L}, C_{S}, C_{O}, and R₃ are all circuit parameters in the circuit in FIG. 1. V_{RD} is a voltage value of the voltage source VDD in FIG. 1.

It can be seen that the test point voltage ν_{TP} presents a first-order low-pass filtering characteristic to the on-state voltage drop ν_{CE-ON}, and a first-order high-pass filtering characteristic to the node voltage ν_{D}. The node voltage ν_{D} presents a high-pass filtering characteristic to the test point voltage ν_{TP} and a low-pass filtering characteristic to the voltage value V_{RD} of the voltage source VDD. The current-limiting resistor R₃ is only a current-limiting resistor of several hundred ohms, the voltage value V_{RD} of the voltage source VDD is constant. Therefore, the node voltage ν_{D} may be considered to be a constant value during the entire low-voltage MOSFET M₁ turn-off time, and the test point voltage ν_{TP} may be equivalent to a first-order low-pass filtering link for the on-state voltage drop ν_{CE-ON}, which may be simplified as:

$${v}_{TP} ( s ) = \frac{{v}_{CE - ON} ( s )}{s {C}_{R} {R}_{L} + s {C}_{S} {R}_{L} + 1}$$

The actual devices such as diodes and operational amplifiers all have certain leakage currents, when the leakage current is considered, the expression of the test point voltage ν_{TP} is as follows:

$${v}_{TP} ( s ) = \frac{{v}_{CE - ON} ( s ) {R}_{J}}{s ( {C}_{R} + {C}_{S} ) {R}_{L} {R}_{J} + 2 {R}_{L} + {R}_{J}}$$

wherein R_{J} is an equivalent resistance of a leakage current in a diode.

According to the expression of the node voltage, in the case of a direct current circuit breaker or a resistive load, the on-state voltage drop is basically a constant value, and for a constant on-state voltage drop, an error may be represented as:

$${v}_{ERR - C} = {lim}_{t \to ∞} ( {v}_{CE - ON} ( t ) - {v}_{TP} ( t ) ) = \frac{2 {R}_{L}}{2 {R}_{L} + {R}_{J}} {v}_{CE - ON}$$

In an actual converter, an inductor is often an indispensable passive device. In a case of an inductive load, a collector current i_{C} is a ramp signal, a responsive on-state voltage drop is also approximated by a ramp signal, and an error may be represented as:

$${v}_{ERR - V} = {k}_{n} \frac{{V}_{LD}}{{L}_{D}} \frac{{R}_{L} {R}_{J}^{2} ( {C}_{R} + {C}_{S} )}{{( {R}_{L} + 2 {R}_{J} )}^{2}} + \frac{2 {R}_{L}}{2 {R}_{L} + {R}_{J}} {v}_{CE - ON}$$

It can be seen that, due to the first-order low-pass filtering characteristic of the measurement circuit, when a constant on-state voltage drop is tracked, the error is only from the equivalent resistance caused by the leakage current in the diode, and when the on-state voltage drop of a ramp signal is tracked, since the first-order circuit link cannot complete the no-difference tracking of the ramp signal, the measurement error is divided into two parts, namely, the error caused by the leakage current in the diode and the error caused by the circuit tracking.

Further, according to a power rating of an actual device, high-resistance series high-voltage resistors R_{L} with different resistances are selected. Since the high-resistance series high-voltage resistor R_{L} bears the bus voltage when the IGBT is turned off, it is necessary to ensure that the power and the withstand voltage of the resistor have a sufficient safety margin. According to an actual requirement, a power dissipation on the resistor is limited to a constant value, and a resistance of the high-resistance series high-voltage resistor R_{L} is calculated using the power dissipation combined with an isolation voltage, specifically:

$$R = \frac{{V}_{CE}}{P}$$

wherein P is an allowed power dissipation on the resistor and is selected to be 4 W in this embodiment, which may be adjusted in practice according to the requirements of the circuit diagram and the heat dissipation conditions. V_{CE} is a voltage between the collector and the emitter.

Further, according to the above error analysis, the most important parameter indexes for the selection of the switching diodes D₁ and D₂ are the leakage current and the junction capacitance C_{R}, and the stability of the parameters to the temperature is also a factor affecting the circuit performance, so that the leakage current and the junction capacitance C_{R} are required to be as small as possible, and the parameter is required to change as little as possible with temperature. In practice, a switching diode with a withstand voltage of around 90 V and a rated current level of mA can meet these requirements, and no special requirements are required for the selection of the switching diode.

Further, for the selection of the operational amplifier U₃, since the tracking parameters are static parameters, there are no strict requirements for the bandwidth of the operational amplifier, but the input impedance is required to be large enough and the input bias current is required to be small. In practice, the operational amplifier U₃ is required to have a bandwidth of 1 MHz or more, an input impedance of more than 1000 MΩ, an input capacitance of 4 pF or less, and an input bias current level of nA. Since the operational amplifier U₃ is already used as a voltage follower at the previous stage, the isolation operational amplifier U₄ only needs to meet the requirement of the system for isolation voltage and has no special requirement for the operational amplifier performance.

Further, for the parameter selection of the RC delay circuit, during the IGBT turn-on/turn-off transient, it takes a certain amount of time for the collector-emitter voltage of the IGBT to change from the bus voltage to the on-state voltage drop. During the turn-on transient of the IGBT, the voltage between the collector and the emitter of the IGBT is dropped from the bus voltage to the on-state voltage drop. To avoid the influence of the high voltage between the collector and the emitter on the measurement, a delay needs to be added to the low-voltage MOSFET M₁ in this case, so that the circuit starts to track the on-state voltage drop after the voltage between the collector and the emitter of the IGBT is dropped to the on-state voltage drop. When the IGBT is turned off, the control signal arrives earlier than the rise of the collector-emitter voltage, so that the circuit is not interfered, and special treatment is not required. FIG. 3 shows waveforms of the operating state of the circuit at key nodes during the IGBT turn-on and turn-off process. The delay time of the RC delay circuit may be represented as:

T_{D}=RC

In practice, this delay time is related to the change time of the voltage between the collector and the emitter of the IGBT and needs to be adjusted according to the switching speed of the IGBT, which is set to about 2 us to fully meet the requirements. The specific values of the parameters of the capacitor and the resistor may be calculated according to a formula.
Step 2: measuring a collector current i_{C} and an on-state voltage drop model at different junction temperatures under an offline condition, and providing a calculation model for online monitoring.

It is generally considered that after the IGBT operates in the saturation region, the on-state voltage drop ν_{CE-ON} is represented as:

$${v}_{CE - ON} = \frac{{mkT}_{j}}{q} ln ( \frac{{i}_{C}}{{i}_{S}} + 1 ) + {i}_{C} ( {R}_{N} + {R}_{CH} )$$

wherein m is an injection coefficient, k is a Boltzmann constant, Tⱼ is a junction temperature, q is a charge, i_{C} is the collector current, i_{S} is a reverse saturation current, R_{N} is a module package resistance of the IGBT module, and R_{CH} is an internal on-resistance of the IGBT.

A partial derivative of the collector current i_{C} is calculated for the on-state voltage drop ν_{CE-ON}, wherein a change rate of the on-state voltage drop ν_{CE-ON} to the collector current i_{C} is represented as:

$${k}_{CE} = \frac{\partial {v}_{CE - ON}}{\partial {i}_{C}} = \frac{{nkT}_{j}}{{qi}_{S}} \frac{1}{{i}_{C} + {i}_{S}} + ( {R}_{N} + {R}_{CH} )$$

It can be seen that the change rate of the on-state voltage drop ν_{CE-ON} to the collector current i_{C} changes with i_{C}; when the collector current i_{C} is within a small change range, the change rate is regarded as a constant, and the on-state voltage drop is represented by piecewise linearization based on the collector current i_{C} as follows:

$${v}_{CE - ON} ( {i}_{C} ) = {k}_{n} {i}_{C} + {V}_{INT - n} n = 1 , 2 … n$$

wherein kₙ is the change rate of on-state voltage drop ν_{CE-ON} to the collector current i_{C} within different collector current i_{C} ranges, which is a specific value of k_{CE} in a certain collector current i_{C} region, and n represents different current ranges; V_{INT-n} is a constant term of an expression in each collector current i_{C} range; kₙ and V_{INT-n} are different in different collector current i_{C} ranges; for kₙ, when the collector current i_{C} is within a small change range, kₙ is considered to be a constant independent of the collector current i_{C} but related to the junction temperature Tⱼ according to k_{CE} expression.

Based on the piecewise linearization in the previous analysis, the basic principle of calculating kₙ may be represented as:

$${k}_{n} = \frac{Δ {v}_{CE - ON}}{Δ {i}_{C}}$$

In practical applications, noise is inevitable. To enhance the anti-interference capability, kₙ is calculated using a least square method by sampling the on-state voltage drop ν_{CE-ON} and the collector current i_{C} multiple times within a certain current range and is represented as:

$${k}_{n} = \frac{\overline{{v}_{CE - ON} {i}_{C}} - \overline{{v}_{CE - ON}} \overline{{i}_{C}}}{\overline{{i}_{C}^{2}} - {( \overline{{i}_{C}} )}^{2}}$$

a fitting coefficient Rₙ² is represented as:

$${R}_{n}^{2} = 1 - \frac{\sum {( {v}_{CE - ON} - \overline{{v}_{CE - ON}} )}^{2}}{\sum {( {v}_{CE - ON} - f ( {i}_{C} ) )}^{2}}$$

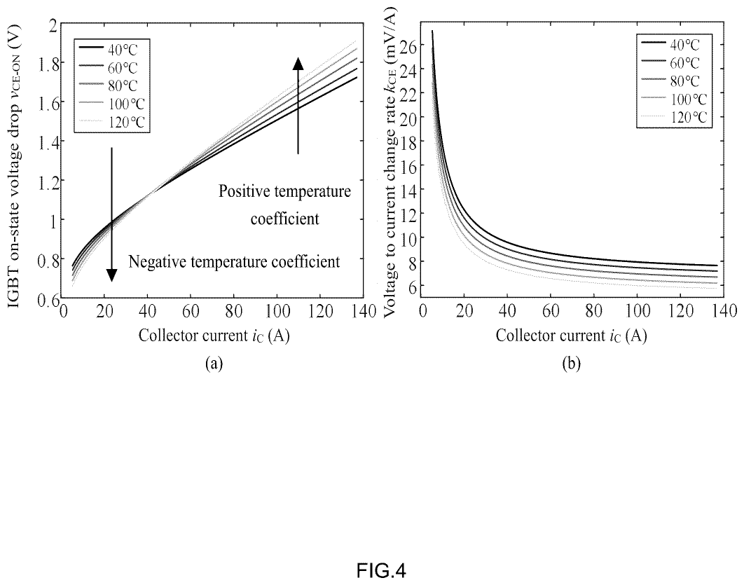

FIG. 4 shows output characteristics of IGBT at different temperatures and a change rate of on-state voltage drop to a collector current at different currents. It can be seen that the on-state voltage drop of the IGBT has a distinct positive temperature coefficient region and a distinct negative temperature coefficient region at different currents, and the turning point of the two regions is about 45 A. The on-state voltage drop has a positive temperature coefficient for the change rate of the collector current i_{C} over the entire current range and remains basically stable at high currents.

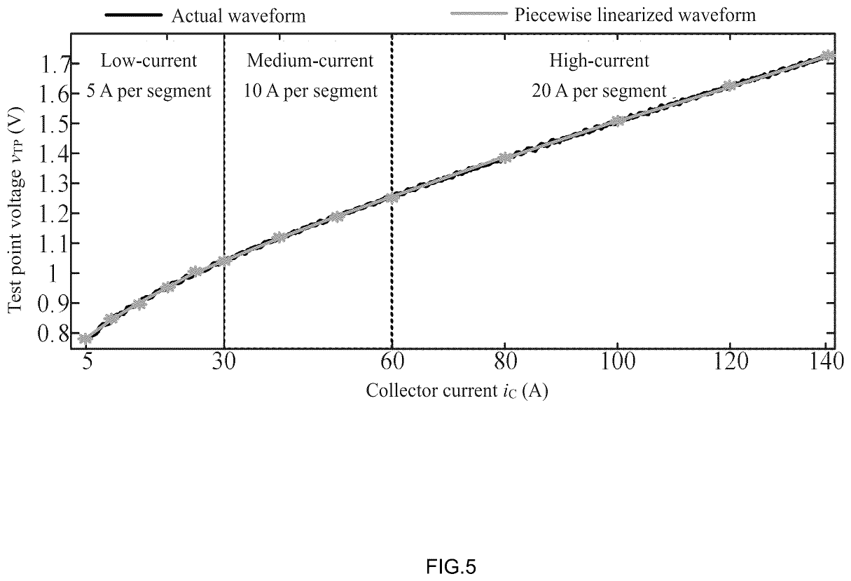

The actual waveform and linearized waveform of the test point voltage VTP in the full current range are shown in FIG. 5. It can be seen that the collector current i_{C} is divided into 3 phases, a low-current phase (5 A to 30 A), a medium-current phase (30 A to 60 A) and a high-current phase (greater than 60 A). Every 5 A is set as a current interval in the low-current phase, every 10 A is set as a present interval in the medium-current phase, and every 20 A is set as an existing interval in the high-current phase. It can be seen that the linearized waveform has a good description.

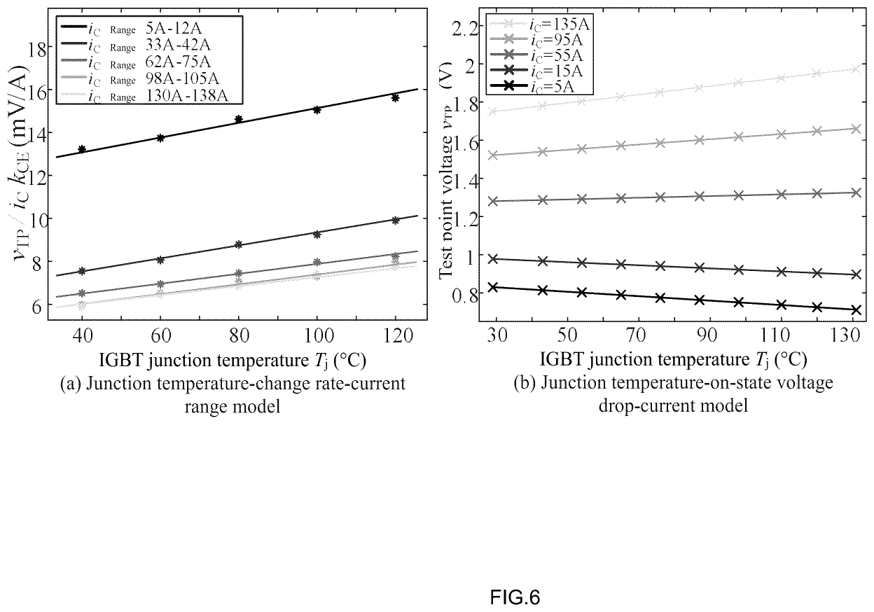

FIG. 6 is a schematic diagram of a junction temperature-current segment-on-state voltage drop versus a current change rate model and a junction temperature-on-state voltage drop-current model. In inductive loads, there is a stable error between the on-state voltage drop ν_{CE-ON} and the test point voltage VTP, so kₙ is used as a thermal parameter. It can be seen that kₙ in the low-current range is much greater than that in the high-current range, and kₙ remains basically stable in the high-current region. When the current range is divided, in low currents, the current range needs to be very narrow, and in high currents, the current range may be wider.
Step 3: performing online monitoring on the junction temperature under online conditions based on the model obtained from offline condition testing.

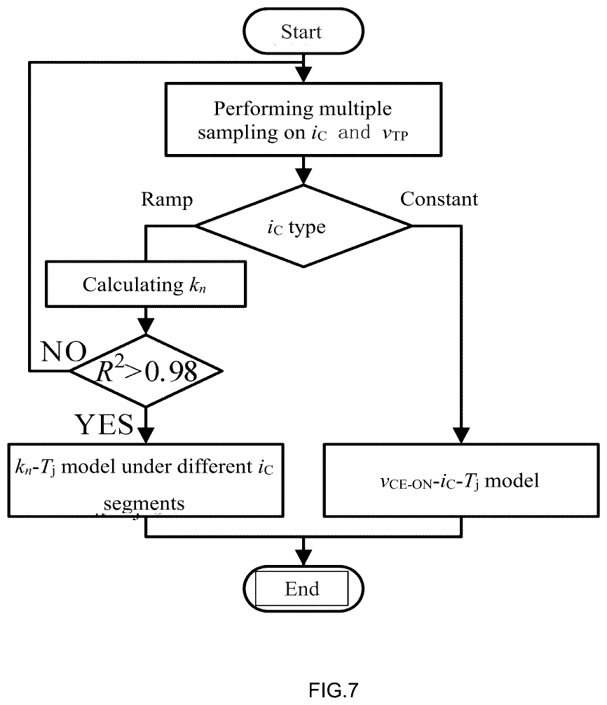

FIG. 7 shows a flow chart of a junction temperature online monitoring strategy. In an actual process, a circuit has large ripple interference, so that the reliability of data is improved by judging a fitting coefficient R², and the monitoring accuracy is further improved.

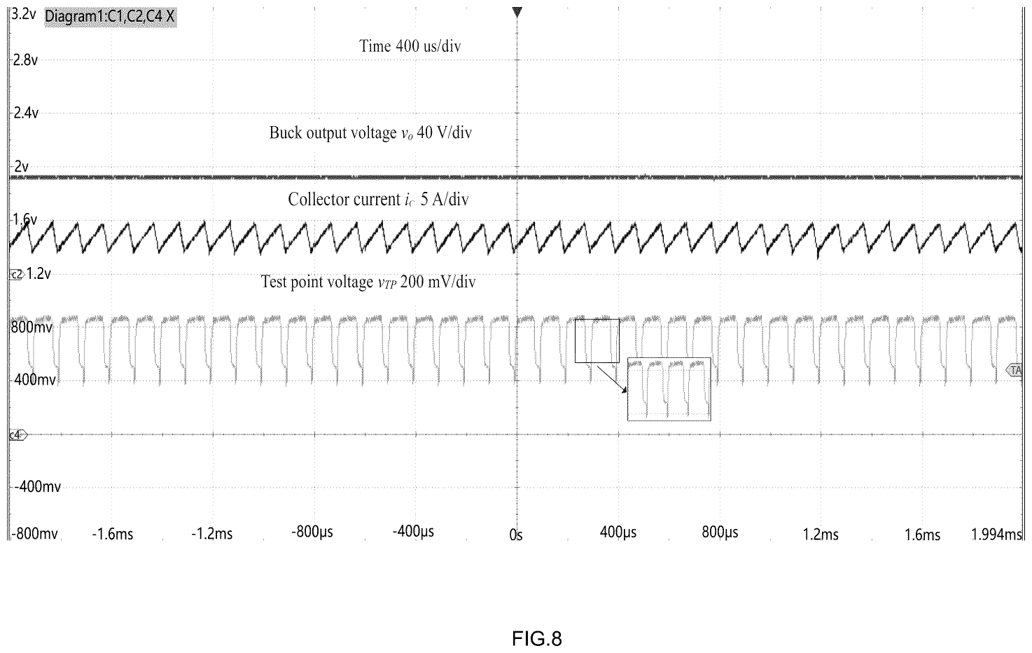

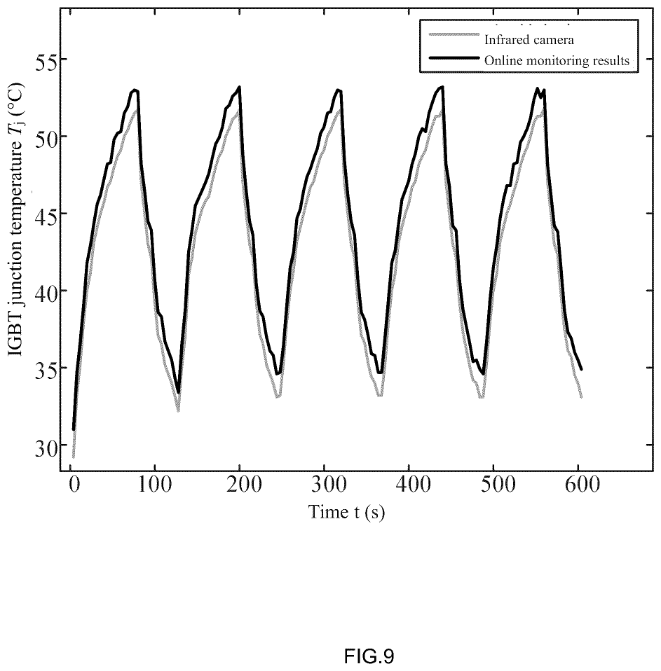

In the online monitoring experiment, a power cycle experiment based on a Buck circuit is used to verify the online monitoring effect of the proposed monitoring circuit and monitoring method on the junction temperature. The Buck power cycle test bench dissipates heat from the IGBT by a heat sink, and a temperature of the IGBT is increased or decreased when the IGBT is running continuously by changing a power of the heat sink. In the present invention, the IGBT is set to have a cycle of 60 s, with 40 s for temperature increase and 20 s for temperature decrease. FIG. 8 is a waveform during junction temperature online monitoring, and FIG. 9 is a schematic diagram of a comparison between monitoring results during the junction temperature online monitoring process and measurement results of an infrared camera. It can be seen that the online monitoring strategy has a good effect on junction temperature online monitoring, and the error of the monitored temperature does not exceed 3.5° C. at most.

1. A resistor voltage-bearing type on-state voltage drop measurement circuit for junction temperature monitoring, comprising: a high-resistance series high-voltage resistor, a first switching diode, a second switching diode, a low-voltage MOSFET, an inverter, a three-state gate, an RC delay circuit consisting of a resistor and a capacitor, a current-limiting resistor, a current-limiting resistor, auxiliary voltage sources VDD and VCC, an operational amplifier, and an isolation operational amplifier;
wherein one end of the high-resistance series high-voltage resistor is connected to a collector of an IGBT, the other end of the high-resistance series high-voltage resistor is connected to a positive electrode of the first switching diode, a negative electrode of the first switching diode is connected to a drain of the low-voltage MOSFET, and a source of the low-voltage MOSFET is connected to an emitter of the IGBT;
a connection between the positive electrode of the first switching diode and the high-resistance series high-voltage resistor is a test point and is connected to an input end of the operational amplifier of an isolation part,
a negative electrode of the second switching diode is connected to the test point, and a positive electrode of the second switching diode is connected to power reference ground; and the auxiliary voltage source VDD is connected to the negative electrode of the first switching diode by the current-limiting resistor;
in a circuit of a logic part, an input signal of the circuit is obtained by inverting a first signal of the IGBT that is sent by a controller, by the inverter, and then the signal is input to an input end of three-state gate by the series RC delay circuit, and an input signal of a control end of the three-state gate is a second signal of the IGBT; after passing through the three-state gate, the second signal of the IGBT becomes a signal with a delay added to a falling edge after inversion, and the second signal is finally used for switching control of the low-voltage MOSFET;
in a circuit of the isolation part, an input signal of the isolation part is from a test point voltage of a measurement part, and the operational amplifier is connected as a voltage follower, and a voltage of the voltage follower is finally used for on-state voltage drop detection by the isolation operational amplifier; and
the measurement circuit also has an output parasitic capacitance from the low-voltage MOSFET, a junction capacitance of the first switching diode and the second switching diode, an input capacitance of the operational amplifier and a PCB parasitic capacitance, which are connected to the test point.

2. The resistor voltage-bearing type on-state voltage drop measurement circuit for junction temperature monitoring according to claim 1, wherein when the IGBT is on-state, the low-voltage MOSFET is turned off according to the second signal, the first switching diode is in a reverse bias state, and the test point voltage is equivalent on-state voltage drop;
when the IGBT is turned off, the low-voltage MOSFET is turned on and turned off according to the second signal, the first switching diode is in a forward bias state, high voltage between the collector and the emitter of the IGBT is born by the high-resistance series high-voltage resistor, and the test point voltage is clamped to the on-state voltage drop of the second switching diode; and during a process of turning on and turning off of the IGBT the high-resistance series high-voltage resistor bears high voltage only in a IGBT turn-off process and does not bear high voltage in other periods; and a control signal of the low-voltage MOSFET is formed by the second signal of the IGBT after conditioning of the logic part.

3. An IGBT junction temperature online monitoring method based on the resistor voltage-bearing type on-state voltage drop measurement circuit according to claim 1, comprising the following steps:
step 1: designing an on-state voltage drop sampling circuit based on the high-resistance series high-voltage resistor and selecting parameters according to an actual application scenario;
according to a power rating of an actual device, high-resistance series high-voltage resistors with different resistances are selected to limit a power dissipation on the high-voltage resistors to a constant value, a resistance of the high-resistance series high-voltage resistor is calculated using the power dissipation combined with an isolation voltage, specifically:
$$R = \frac{{V}_{CE}}{P}$$
wherein P is an allowed power dissipation on the high voltage resistors, and V_{CE} is a voltage between the collector and the emitter of the IGBT;
for the first switching diode and the second switching diode, any switching diode with a withstand voltage of about 90 V and a rated current level of mA meets requirements;
the operational amplifier requires a bandwidth of more than 1 MHz, an input impedance greater than 1000 MΩ, an input capacitance of less than 4 PF, and an input bias current level of nA; and the isolation operational amplifier only needs to meet a requirement of a system on isolation voltage;
for parameter selection of the RC delay circuit, a delay is added to the low-voltage MOSFET when the IGBT is turned on, and a delay time of the RC delay circuit is represented as:
T_{D}=RC
specific values of parameters of the capacitor and the resistor may be calculated according to a formula;
step 2: measuring a collector current and an on-state voltage drop model at different junction temperatures under an offline condition, and providing a calculation model for online monitoring;
when IGBT operates in a saturation region, the on-state voltage drop is represented as:
$${v}_{CE - ON} = \frac{{mkT}_{j}}{q} ln ( \frac{{i}_{C}}{{i}_{S}} + 1 ) + {i}_{C} ( {R}_{N} + {R}_{CH} )$$
wherein m is an injection coefficient, k is a Boltzmann constant, Tⱼ is a junction temperature, q is a charge, i_{C} is the collector current, i_{S} is a reverse saturation current, R_{N} is a module package resistance of an IGBT, and R_{CH} is an internal on-resistance of the IGBT;
a partial derivative of the collector current is calculated for the on-state voltage drop, wherein a change rate of the on-state voltage drop to the collector current is represented as:
$${k}_{CE} = \frac{\partial {v}_{CE - ON}}{\partial {i}_{C}} = \frac{{nkT}_{j}}{{qi}_{S}} \frac{1}{{i}_{C} + {i}_{S}} + ( {R}_{N} + {R}_{CH} )$$
wherein the change rate of the on-state voltage drop to the collector current is changed with the collector current; when the collector current is within a small change range, the change rate is regarded as a constant, and the on-state voltage drop is represented by piecewise linearization based on the collector current as follows:
$${v}_{CE - ON} ( {i}_{C} ) = {k}_{n} {i}_{C} + {V}_{INT - n} n = 1 , 2 … n$$
wherein kₙ is the change rate of on-state voltage drop to the collector current within different collector current ranges, which is a specific value of k_{CE} in a certain collector current region, and n represents different current ranges; V_{INT-n} is a constant term of an expression in each collector current range; kₙ and V_{INT-n} are different in different collector current ranges; for kₙ, when the collector current is within a small change range, kₙ is considered to be a constant independent of the collector current but related to the Tⱼ according to k_{CE} expression;
kₙ is calculated using a least square method by sampling the on-state voltage drop and the collector current multiple times within a certain current range and is represented as:
$${k}_{n} = \frac{\overline{{v}_{CE - ON} {i}_{C}} - \overline{{v}_{CE - ON} {i}_{C}}}{\overline{{i}_{C}^{2}} - {( \overline{{i}_{C}} )}^{2}}$$
a fitting coefficient Rₙ² is represented as:
$${R}_{n}^{2} = 1 - \frac{\sum {( {v}_{CE - ON} - \overline{{v}_{CE - ON}} )}^{2}}{\sum {( {v}_{CE - ON} - f ( {i}_{C} ) )}^{2}}$$
step 3: performing online monitoring on the junction temperature under online conditions based on the collector current and the on-state voltage drop model obtained from offline condition testing;
in an online monitoring experiment, a power cycle experiment based on a Buck circuit is used to verify an online monitoring effect of a proposed monitoring circuit and monitoring method on the junction temperature, the Buck power cycle test bench dissipates heat from the IGBT by a heat sink, and a temperature of the IGBT is increased or decreased when the IGBT is running continuously by changing a power of the heat sink.
